(19) United States
(12) Patent Application Publication
(10) Pub. No.: US 2026/0211032 A1
(43) Pub. Date: Jul. 23, 2026

(54) OPTICAL COUPLING VERIFICATION METHOD

(71) Applicant: HERMES TESTING SOLUTIONS INC., Hsinchu City (TW)

(72) Inventor: Wen-Yuan Hsu, Hsinchu City (TW)

(73) Assignee: HERMES TESTING SOLUTIONS INC., Hsinchu City (TW)

(21) Appl. No.: 19/312,280

(22) Filed: Aug. 27, 2025

Related U.S. Application Data
(60) Provisional application No. 63/747,347, filed on Jan. 21, 2025.

(30) Foreign Application Priority Data
Apr. 8, 2025 (TW) 114113129

(51) Int. Cl. G01R 31/311

(52) U.S. Cl. CPC G01R 31/311

(57) ABSTRACT

An optical coupling verification method is used in a silicon photonics wafer testing system including a wafer prober, an optical coupling actuator, an optical measurement instrument, and an integrated control module electrically connected to the wafer prober, optical coupling actuator, and optical measurement instrument. An optical fiber array is disposed on the optical coupling actuator on an optical path of the optical measurement instrument. The method includes: loading a verification kit into the wafer prober; and driving, by the integrated control module, an upward-facing camera of the wafer prober to be aligned with the optical fiber array. The integrated control module drives a downward-facing camera of the wafer prober to be aligned with the verification kit, obtains a relative position relation between the optical fiber array and the verification kit in the wafer prober, and performs optical coupling verification to obtain characteristics variation of light of the optical path.

### CROSS-REFERENCE TO RELATED APPLICATION

This application claims the priority benefit of U.S. Provisional Application No. 63/747,347, filed on January 21, 2025 and Taiwan Application No. 114113129, filed on April 8, 2025. The entirety of each of the above-mentioned patent applications is hereby incorporated by reference herein and made a part of this specification.

### BACKGROUND

### Technical Field

The disclosure relates to an optical coupling verification method.

### Description of Related Art

Photonics integrated circuits (PICs) are well-known technology in the field of telecommunications and is driving the development of high-speed networks and artificial intelligence (AI). This is mainly attributed to the rapid development of optical transceiver modules, which are smaller and faster than larger discrete optics. From both commercial and research perspectives, PICs are also beginning to make a difference in other fields (e.g., chip laboratories, laser technology, or quantum computing).

At present, testing of silicon photonics wafers is performed directly after product completion, and the product quality is then accordingly determined. However, when a product is determined to be defective due to loss and it is not possible to clearly identify which part (section) of the optical path of the silicon photonics wafer caused the loss, yield misreporting thereby occurs. Further, the components along the test path include the laser source at the front end of the product, optical fibers, optical fiber arrays, as well as gratings, optical waveguides, and optical components on the silicon photonics wafer. In other words, if the loss of the product's previous test path cannot be ensured (or known) and controlled below the preset value before testing, the product yield during subsequent testing will be affected.

### SUMMARY

The disclosure provides an optical coupling verification method capable of detecting and verifying optical characteristics on an optical path of a silicon photonics wafer testing system before optical coupling, optical testing, or opto-electronic testing is performed on a silicon photonics wafer to be tested of the testing system, so that the accuracy and discrimination rate of the testing system are ensured.

The disclosure provides an optical coupling verification method used in a silicon photonics wafer testing system including a wafer prober, an optical coupling actuator, an optical measurement instrument, and an integrated control module. The integrated control module is electrically connected to the wafer prober, the optical coupling actuator, and the optical measurement instrument. An optical fiber array is disposed on the optical coupling actuator and located on an optical path generated by the optical measurement instrument. The optical coupling verification method includes the following steps. A verification kit is loaded into the wafer prober. The integrated control module drives an upward-facing camera of the wafer prober to be aligned with the optical fiber array. The integrated control module drives a downward-facing camera of the wafer prober to be aligned with the verification kit. The integrated control module obtains a relative position relation between the optical fiber array and the verification kit in the wafer prober. The integrated control module drives and performs optical coupling verification to obtain characteristics variation of light of the optical path.

To sum up, in the optical coupling verification method, the verification kit is loaded into the wafer prober of the silicon photonics wafer testing system, so that the integrated control module of the silicon photonics wafer testing system is allowed to drive the upward-facing camera and downward-facing camera of the wafer prober. The upward-facing camera is used to be aligned with the optical fiber array configured in the optical coupling actuator and positioned on the optical path generated by the optical measurement instrument, while the downward-facing camera is used to be aligned with the verification kit. In this way, the integrated control module is enabled to obtain the relative position relation between the optical fiber array and the verification kit in the wafer prober. Accordingly, the integrated control module then drives the wafer prober, the optical measurement instrument, and the optical coupling actuator to perform optical coupling verification on the optical fiber array and the verification kit, so as to obtain the characteristics variation of light of the optical path.

Accordingly, in the silicon photonics wafer testing system, it can be confirmed that whether the optical characteristics on the optical path in the system meet the required condition for testing before optical coupling or subsequent testing is performed on the silicon photonics wafer to be tested. In this way, subsequent optical coupling or testing results are prevented from being affected by internal system issues, and the accuracy and identification rate of the testing system are further improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flow chart of an optical coupling verification method according to the disclosure.

FIG. 2A to FIG. 2D are schematic views of the optical coupling verification method.

FIG. 3A to FIG. 3C are verification kits according to different embodiments.

FIG. 4 is a schematic view of a step according to another embodiment of the disclosure.

FIG. 5A and FIG. 5B are schematic views of subsequent operations that can be performed by a silicon photonics wafer testing system after verification.

FIG. 6A to FIG. 6C are schematic views of processes of a verification method according to another embodiment.

FIG. 7 is a schematic view of processes of a verification method according to another embodiment.

### DESCRIPTION OF THE EMBODIMENTS

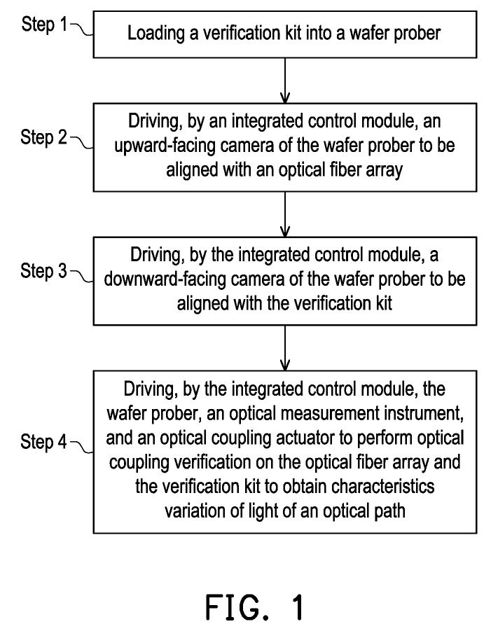

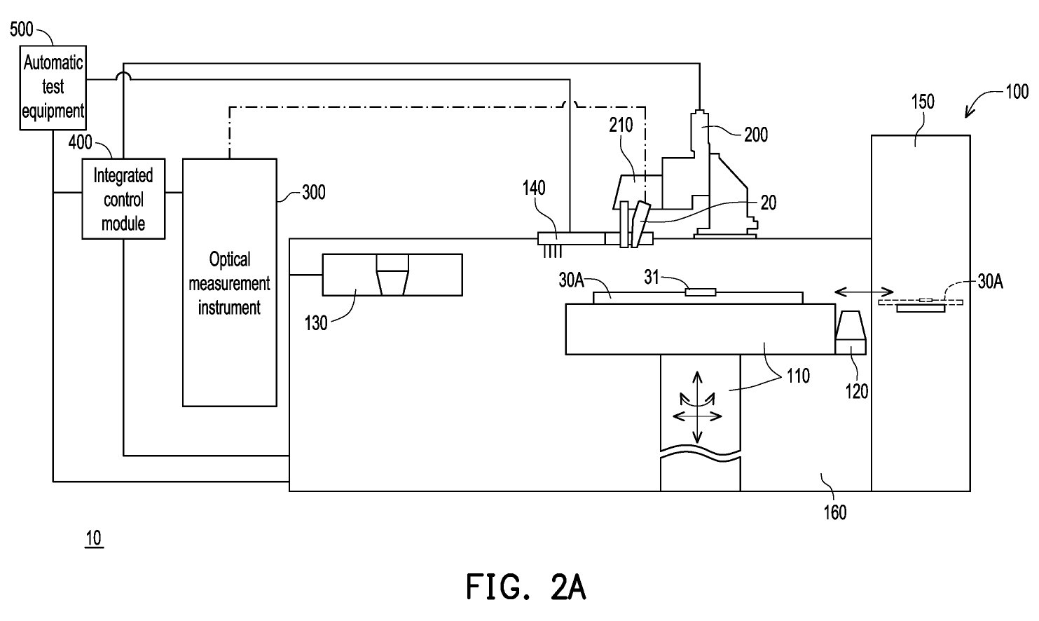

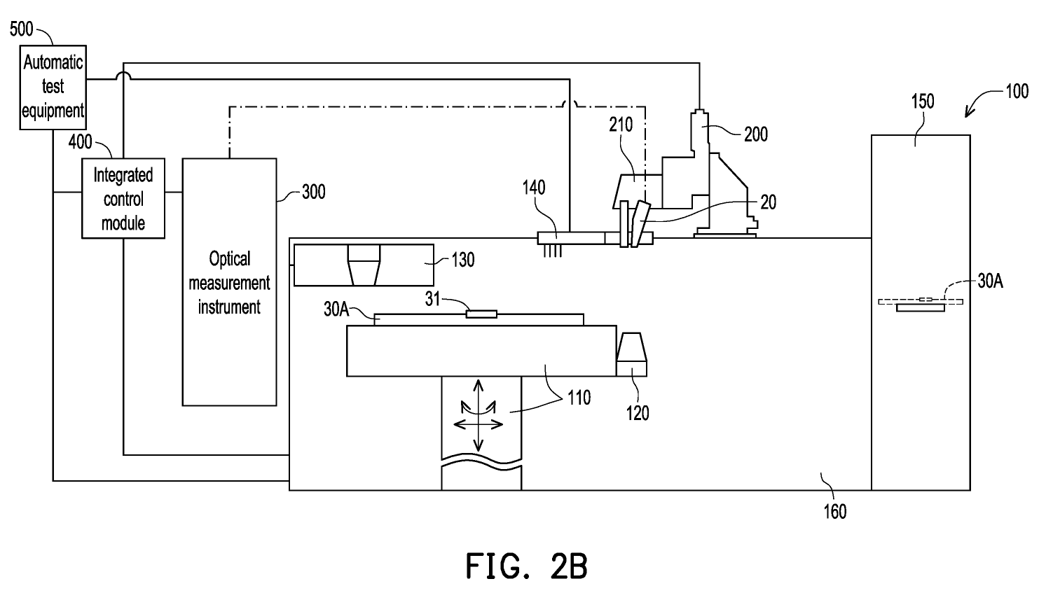

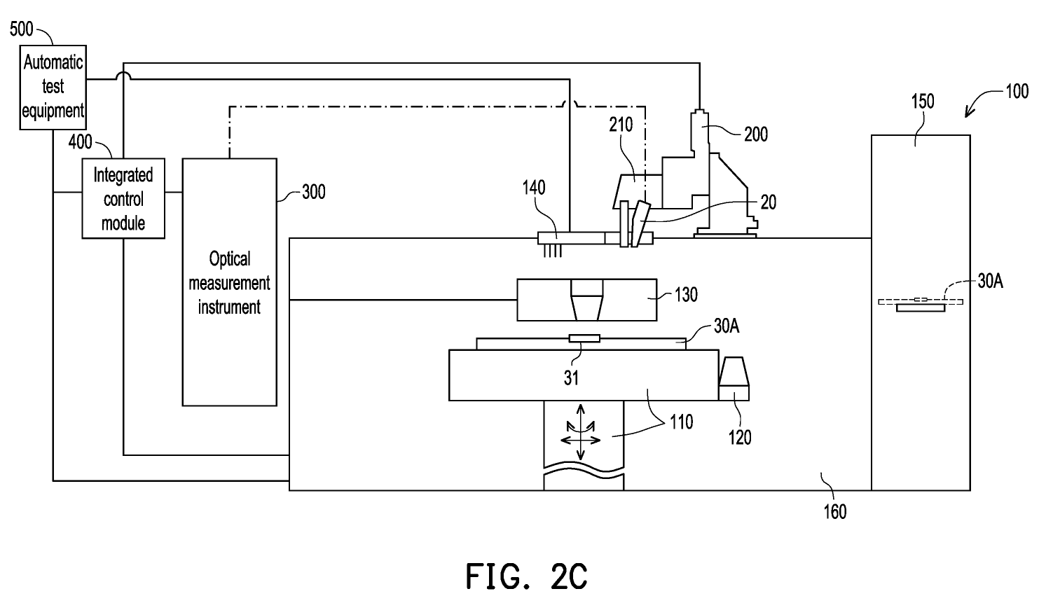

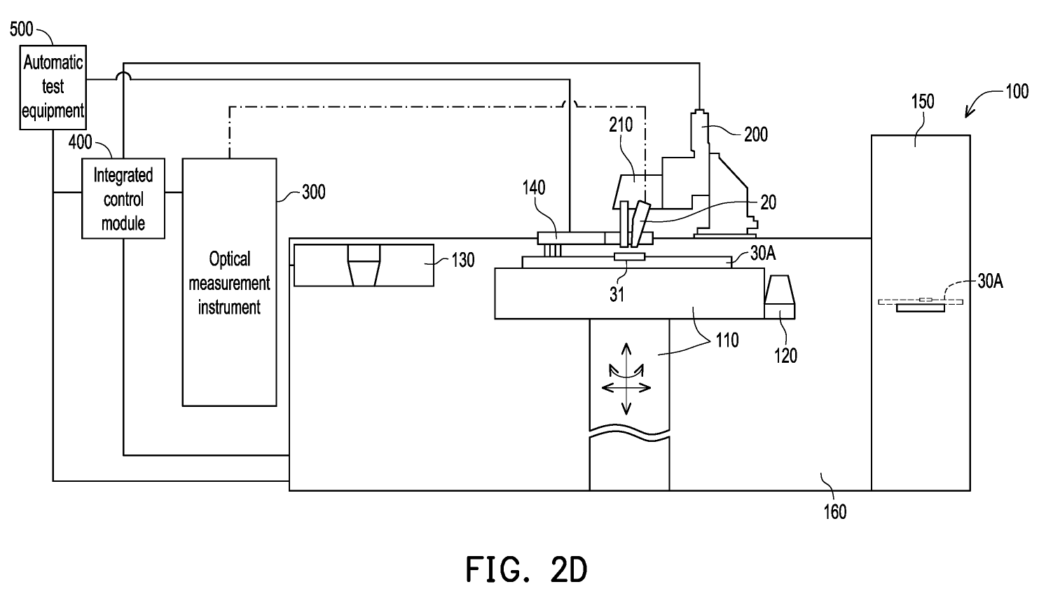

FIG. 1 is a flow chart of an optical coupling verification method according to the disclosure. FIG. 2A to FIG. 2D are schematic views of the optical coupling verification method. Referring to FIG. 1 and FIG. 2A first, in this embodiment, an optical coupling verification method is used in a silicon photonics wafer testing system 10 as shown in FIG. 2A, where the silicon photonics wafer testing system 10 includes a wafer prober 100, an optical coupling actuator 200, an optical measurement instrument 300, an integrated control module 400, and an automatic test equipment 500 (ATE). The integrated control module 400 is electrically connected to the wafer prober 100, the optical coupling actuator 200, and the optical measurement instrument 300. An optical fiber array 20 is disposed on the optical coupling actuator 200 and located on an optical path (shown as the dash-dot line in the figure) generated by the optical measurement instrument 300. The automatic test equipment 500 is integrated with the wafer prober 100 and electrically connected to the integrated control module 400. In this way, the integrated control module 400 is allowed to drive the automatic test equipment 500 to detect electrical characteristics or opto-electronic characteristics of the silicon photonics wafer 30.

Further, in this embodiment, the wafer prober 100 includes a probe testing platform 160, a wafer transporter 150, a stage 110, an upward-facing camera 120, a downward-facing camera 130, and a probe card 140. The wafer transporter 150 is disposed beside the probe testing platform 160, and is used to transport an object into the probe testing platform 160 and load the object onto the stage 110, or to remove the object from the stage 110. The stage 110 of this embodiment is a movable stage, which, for example, is able to perform lifting and coaxial rotation as a rotary table, or add a driving module that can perform horizontal movement within the probe testing platform 160 based on the aforementioned rotary table. The upward-facing camera 120 is disposed on a side surface of the stage 110 to move with the stage 110, and the downward-facing camera 130 is movably disposed within the probe testing platform 160, so as to facilitate execution of subsequent alignment and testing operations.

In addition, the optical coupling actuator 200 is installed on the probe testing platform 160. The probe card 140 is detachably disposed on the probe testing platform 160 and electrically connected to the automatic test equipment 500. The optical fiber array 20 is clamped on a fiber holder 210 of the optical coupling actuator 200 and driven by the optical coupling actuator 200, so that during processes of optical coupling or related testing, the optical fiber array 20 passes through the probe card 140 and extends into the probe testing platform 160 to face the stage 110.

As described in the foregoing paragraphs, in order to verify whether characteristics variation of light of the optical path from the optical measurement instrument 300 to the optical fiber array 20 meets the needs for optical coupling or testing before optical coupling or testing on the silicon photonics wafer is performed, in the disclosure, a verification method is provide to act as a preliminary verification before the formal operation of the silicon photonics wafer testing system 10. First, in step 1, the integrated control module 400 drives the wafer prober 100 to load a verification kit 30A into the wafer prober 100. That is, the verification kit 30A (equivalent to the aforementioned object) is moved into the probe testing platform 160 via the wafer transporter 150 and is loaded onto the stage 110.

Next, referring to FIG. 1 and FIG. 2B, in step 2, the integrated control module 400 drives the upward-facing camera 120 of the wafer prober 100 to perform alignment on the optical fiber array 20, so as to obtain corresponding position coordinates of the optical fiber array 20 in the wafer prober 100. Next, referring to FIG. 1 and FIG. 2C, in step 3, the integrated control module 400 drives the downward-facing camera 130 of the wafer prober 100 to perform alignment on the verification kit 30A, so as to obtain corresponding position coordinates of the verification kit 30A in the wafer prober 100.

After the above steps 2 and 3 are completed, the integrated control module 400 may then obtain a relative position relation between the optical fiber array 20 and the verification kit 30A in an architecture of the wafer prober 100. Accordingly, referring to FIG. 1 and FIG. 2D, in step 4, the integrated control module 400 drives the wafer prober 100, the optical measurement instrument 300, and the optical coupling actuator 200 to perform optical coupling verification on the optical fiber array 20 and the verification kit 30A, so as to obtain the characteristics variation of light on the optical path. Herein, the characteristics variation of light is, for example, loss of light energy.

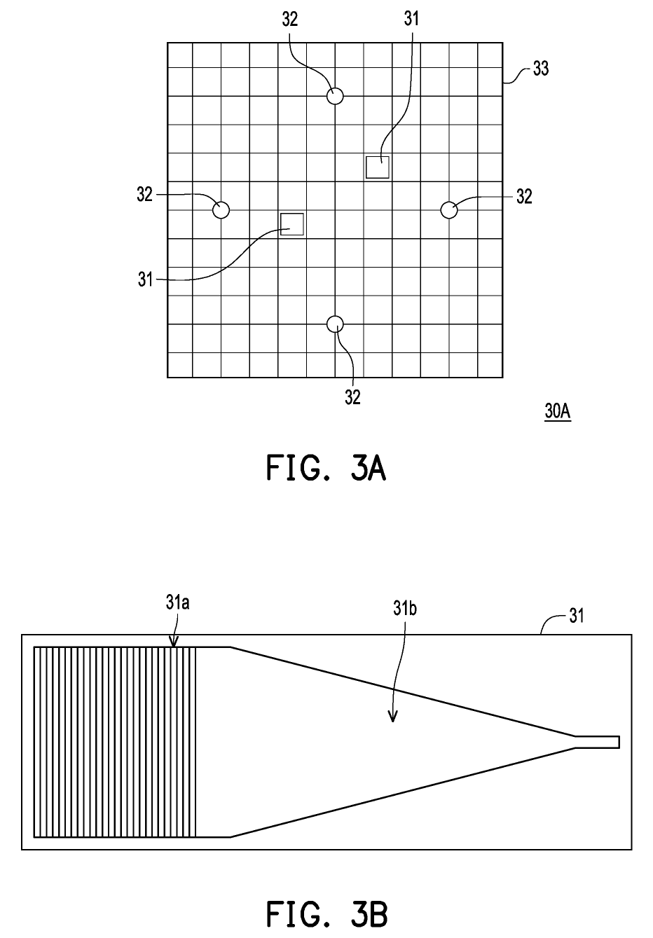

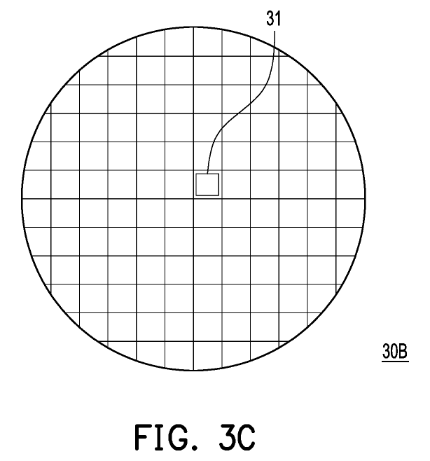

FIG. 3A to FIG. 3C are verification kits according to different embodiments. First, referring to FIG. 3A and FIG. 3B, the verification kit 30A shown is a tray 33 carrying a standard chip 31, and the tray 33 has a mark 32. In this way, the process in FIG. 1 may be modified accordingly as follows. The tray 33 is loaded onto the stage 110 of the wafer prober 100. Further, the downward-facing camera 130 are aligned with the mark 32 and the standard chip, so as to obtain corresponding position coordinates of the tray 33 and the standard chip 31 thereon in the probe testing platform 160 of the wafer prober 100. Herein, the standard chip 31 has an optical waveguide 31b of a specific length and a coupler (a grating coupler 31a is treated as an example herein) corresponding to the number of the optical fiber array 20. As expected, standard chips 31 of different specifications may be placed on the same tray 33, which means that these standard chips 31 may be set to different standards by changing the length of the optical waveguide 31b and the specification of the coupler, so that different forms of optical verification for the optical path are met.

Referring to FIG. 3C, different from the previous example where multiple standard chips 31 are carried by the tray 33, in this embodiment, a verification kit 30B is essentially a complete silicon photonics wafer including multiple standard chips 31. Therefore, the process in FIG. 1 may be modified accordingly as follows. The silicon photonics wafer is loaded onto the stage 110 of the wafer prober 100. Further, the downward-facing camera 130 are aligned with the silicon photonics wafer and at least one standard chip 31, while the remaining steps remain as previously described.

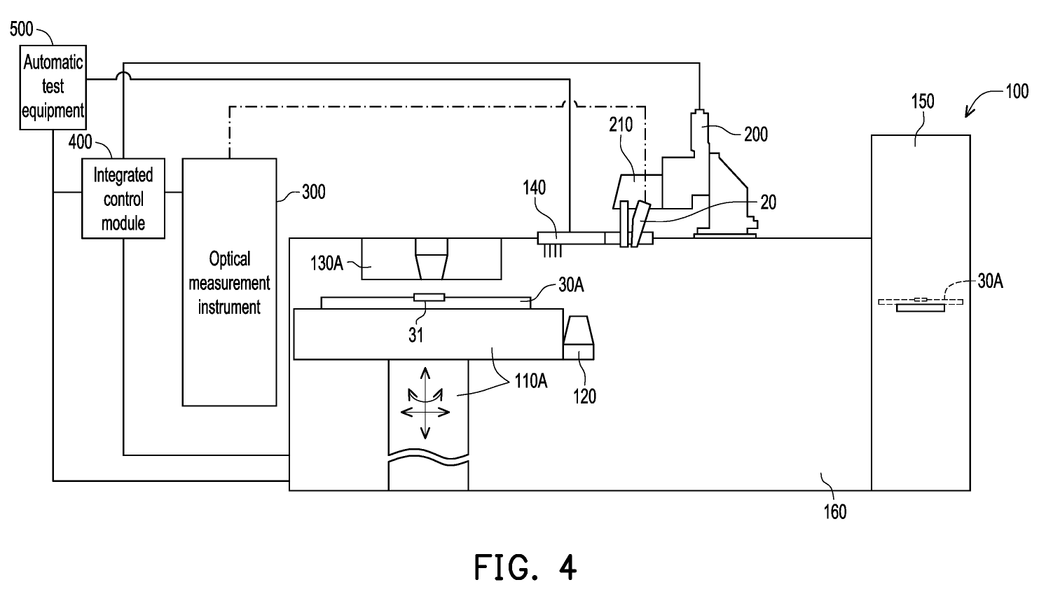

FIG. 4 is a schematic view of a step according to another embodiment of the disclosure. By referring to FIG. 4 and comparing with FIG. 2C of the previous embodiment, it can be clearly understood that in this embodiment, the downward-facing camera 130A is fixed in the probe testing platform 160. Therefore, the alignment step of this embodiment needs to be modified accordingly as follows. The integrated control module 400 drives the stage 110 to move the verification kit 30A thereon to a position under the downward-facing camera 130A for alignment.

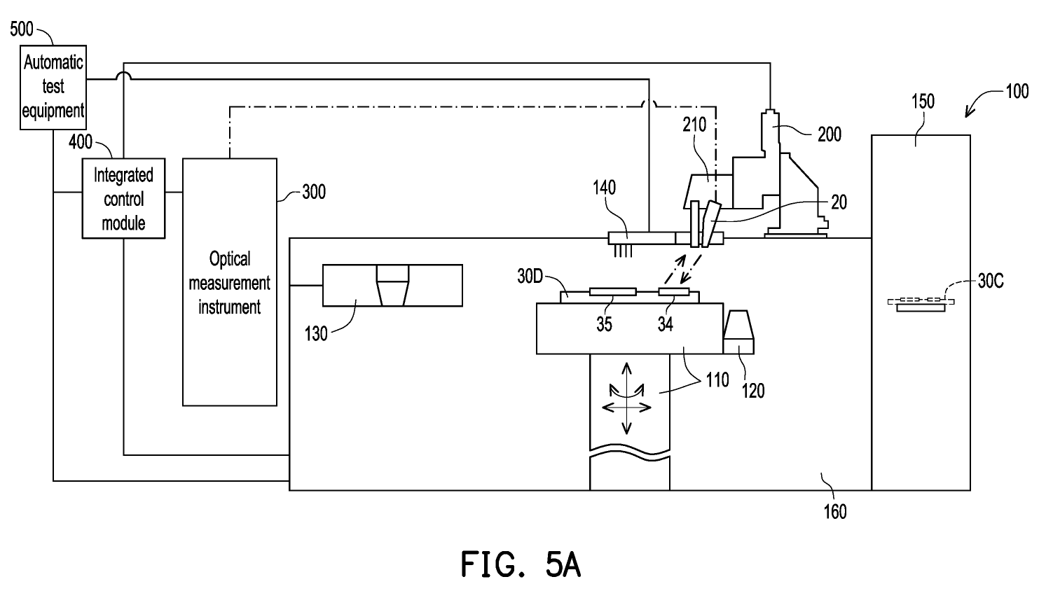

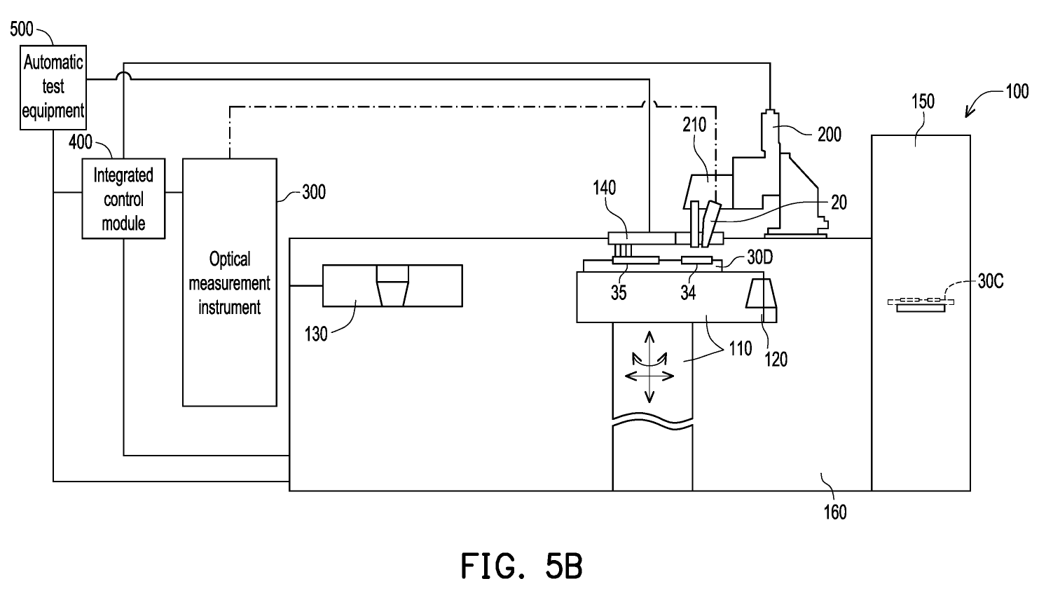

FIG. 5A and FIG. 5B are schematic views of subsequent operations that can be performed by a silicon photonics wafer testing system after verification. Referring to both FIG. 5A and FIG. 5B, it should be noted that the optical coupling, optical testing, and opto-electronic testing shown are merely examples to illustrate the subsequent operations that the silicon photonics wafer testing system 10 may perform after the aforementioned verification is completed. When the characteristics variation of light on the optical path obtained in the aforementioned step 4 meets a preset condition, for example, when the loss of light energy is below a preset value, it is equivalent to verifying that an optical capability of the silicon photonics wafer testing system 10 for optical coupling or testing meets the needs, therefore subsequent operations may be smoothly performed. That is, a silicon photonics wafer to be tested 30D is loaded onto the stage 110 in the wafer prober 100, and the optical measurement instrument 300 and the optical coupling actuator 200 are driven to perform optical coupling between the optical fiber array 20 and a coupler 34 (for example, a grating coupler or an edge coupler) on the silicon photonics wafer to be tested 30D. Further, after the optical coupling is completed, optical testing is performed on the silicon photonics wafer to be tested 30D, as shown in FIG. 5A. Additionally, as shown in FIG. 5B, whether during the optical coupling process or the optical testing and the opto-electronic testing process, the probe card 140 of the wafer prober 100 may be further brought into contact with an electrical bonding pad 35 of the silicon photonics wafer to be tested 30D, so that a relative position relation of the electrical bonding pad 35 in the wafer prober 100 is accordingly obtained, so as to facilitate alignment and enable the execution of required opto-electronic testing as well.

In contrast, when the characteristics variation of light on the optical path obtained in the aforementioned step 4 does not meet the preset condition, for example, when the loss of light energy is above a preset value, it indicates that the current optical capability does not meet the needs. Therefore, adjustment, replacement, or maintenance of a light source and related components on the optical path is needed, followed by re-verification, until the needs are met to ensure that subsequent optical coupling and testing operations can be performed without issues.

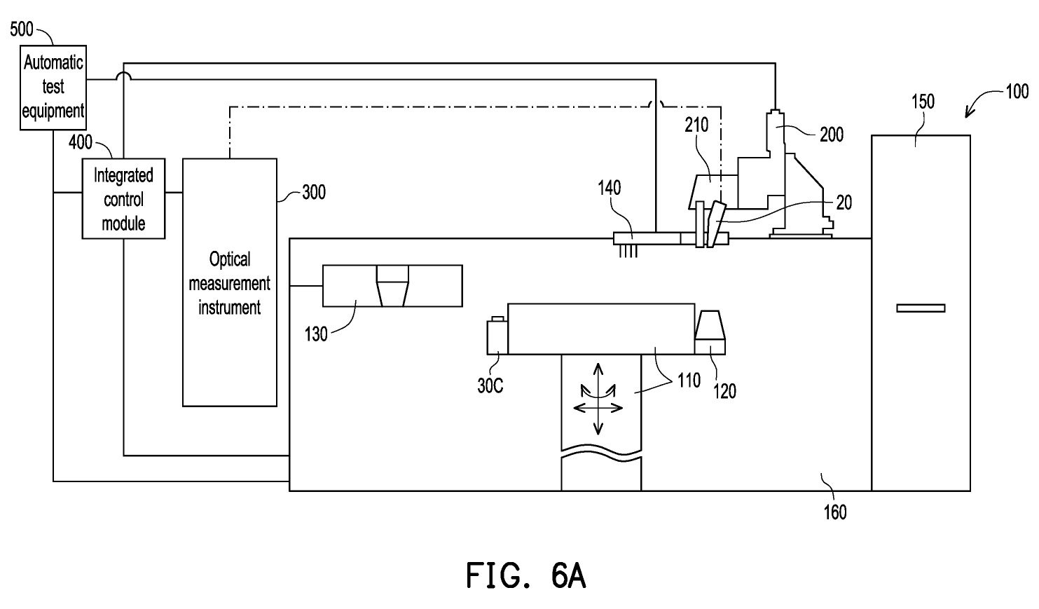

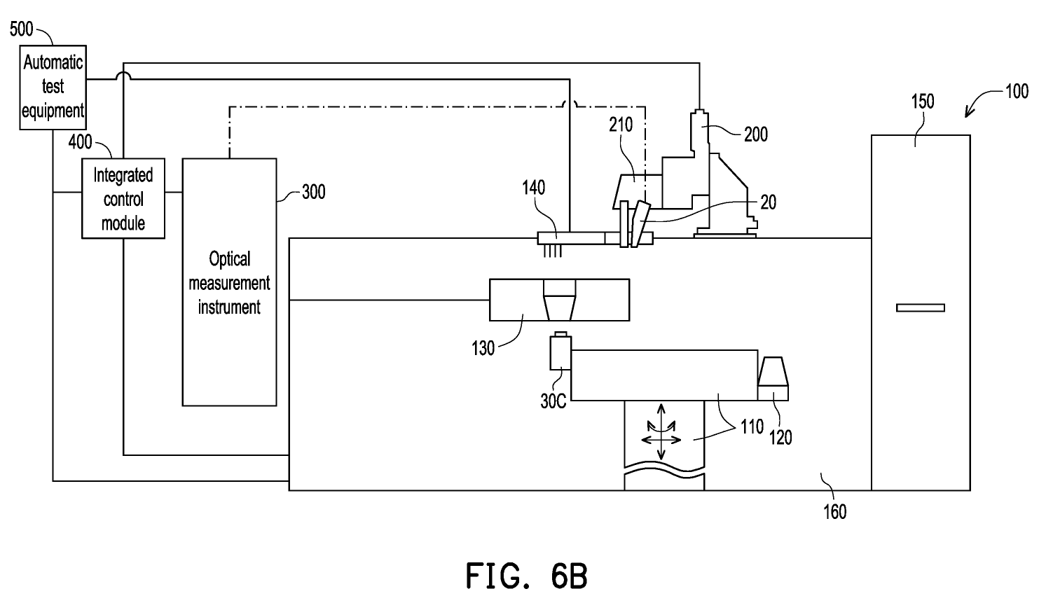

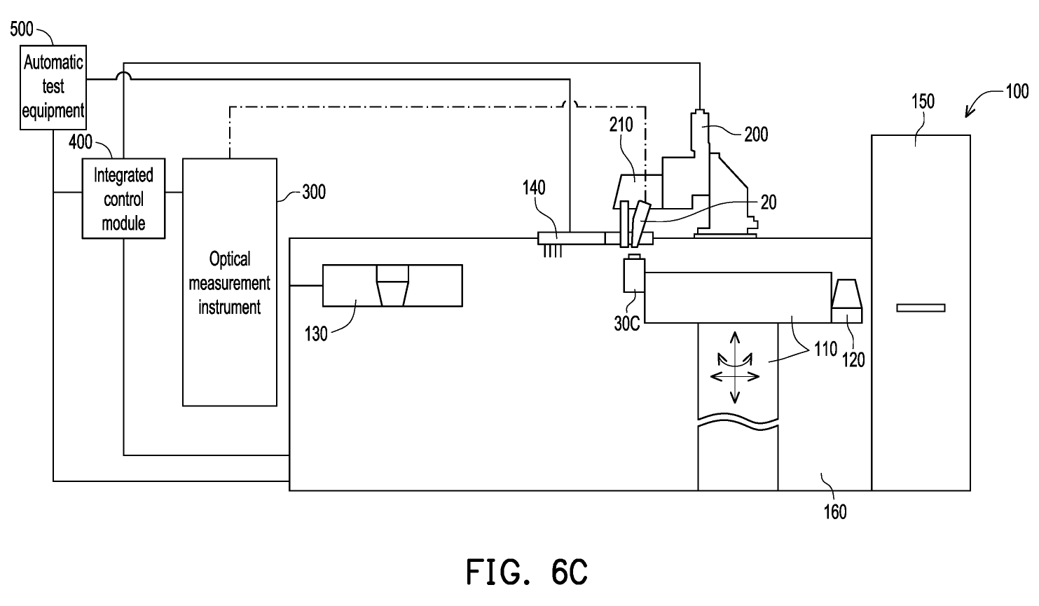

FIG. 6A to FIG. 6C are schematic views of processes of a verification method according to another embodiment. Referring to FIG. 6A to FIG. 6C and the steps shown in FIG. 1, in this embodiment, a verification kit 30C is an optical power meter capable of directly detecting characteristics of light (and their variations), such as a spherical integrating sphere, a planar photo detector, or a power meter. Accordingly, as shown in FIG. 6A, step 2 is executed to align the upward-facing camera 120 with the optical fiber array 20. Subsequently, step 3 needs to be modified accordingly as follow. The integrated control module 400 drives the downward-facing camera 130 of the wafer prober 100 to be aligned with an optical interface of the optical power meter, as shown in FIG. 6B. In this embodiment, the upward-facing camera 120 and the optical power meter are disposed on the side surface of the stage 110 to move with the stage 110 in the probe testing platform 160. Further, the optical power meter is achievable to be raised and lowered on the side surface, so that during the transition from FIG. 6A to FIG. 6B, the optical power meter can be raised above a plane of the stage 110 to facilitate its alignment with the downward-facing camera 130. Herein, in this embodiment, the configuration form of the optical power meter in the probe testing platform 160 is not limited. In an embodiment that is not shown, the wafer prober 100 further includes a moving shaft, which can move independently in the probe testing platform 160 and is in a state separate from the stage 110. Further, the optical power meter is configured on the moving shaft, to facilitate independent control of the moving shaft by the integrated control module 400.

Finally, in step 4 as shown in FIG. 6C, the integrated control module 400 drives the stage 110 to move the optical power meter to the corresponding position of the optical fiber array 20, to facilitate the execution of optical coupling verification. Compared to the embodiments of the foregoing paragraphs which use the standard chip 31 as a comparison reference, in this embodiment, the characteristics of light of the current optical path is directly measured using the optical power meter, providing an operator with intuitive judgment or directly providing the operator with OK or NG warning signals through the integrated control module 400.

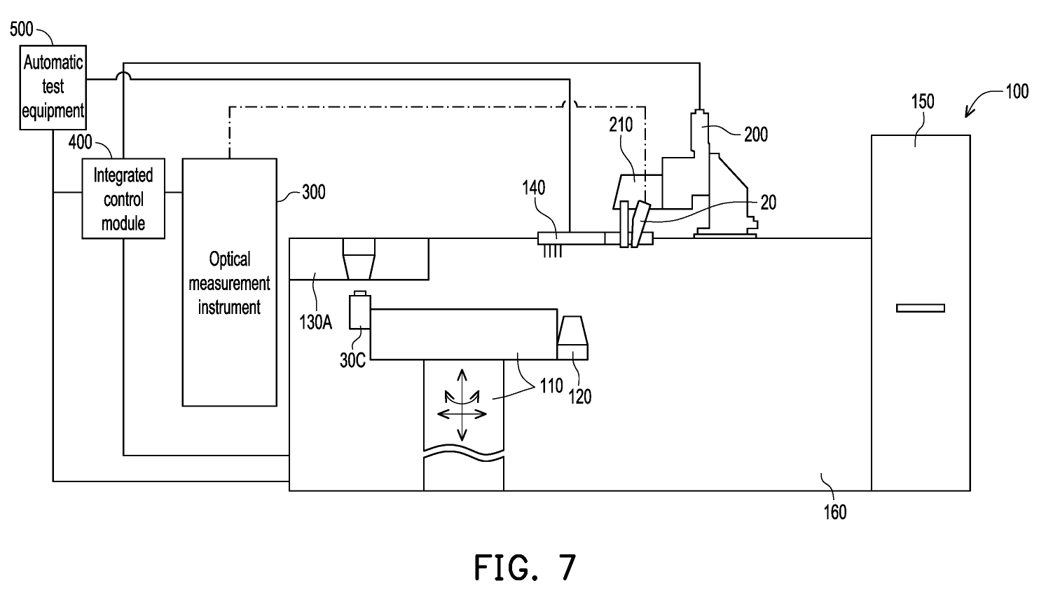

FIG. 7 is a schematic view of processes of a verification method according to another embodiment. Similar to what is shown in FIG. 4 and in the verification process shown in FIG. 6A to FIG. 6C, a fixed downward-facing camera 130A is used to be aligned with the optical power meter. That is, the downward-facing camera 130A is fixed on the left side of the probe testing platform 160, and instead, the stage 110 is driven to move the optical power meter to the downward-facing camera 130A for alignment.

In view of the foregoing, in the embodiments of the disclosure, in the optical coupling verification method, the verification kit is loaded into the wafer prober of the silicon photonics wafer testing system, so that the integrated control module of the silicon photonics wafer testing system is allowed to drive the upward-facing camera and downward-facing camera of the wafer prober. The upward-facing camera is used to be aligned with the optical fiber array configured in the optical coupling actuator and positioned on the optical path generated by the optical measurement instrument, while the downward-facing camera is used to be aligned with the verification kit. In this way, the integrated control module is enabled to obtain the relative position relation between the optical fiber array and the verification kit in the wafer prober. Accordingly, the integrated control module then drives the wafer prober, the optical measurement instrument, and the optical coupling actuator to perform optical coupling verification on the optical fiber array and the verification kit, so as to obtain the characteristics variation of light of the optical path.

In an embodiment, the verification kit is a chip housed on a tray. The chip includes an optical waveguide with at least one length and a coupler corresponding to the number of the optical fiber array, so that verification of different specifications for the light source, various optical components, and the optical fiber array on the optical path is provided. In an embodiment, the verification kit is a silicon photonics wafer including multiple chips, in order to achieve the same verification effect as mentioned in the foregoing paragraphs. In another embodiment, the verification kit is an optical power meter that can directly detect the characteristics of light, providing the operator with intuitive verification results.

Accordingly, in the silicon photonics wafer testing system, it can be confirmed that whether the optical characteristics on the optical path in the system meet the required condition for testing before optical coupling or subsequent testing is performed on the silicon photonics wafer to be tested. In this way, subsequent optical coupling or testing results are prevented from being affected by internal system issues, and the accuracy and identification rate of the testing system are further improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An optical coupling verification method used in a silicon photonics wafer testing system comprising a wafer prober, an optical coupling actuator, an optical measurement instrument, and an integrated control module, wherein the integrated control module is electrically connected to the wafer prober, the optical coupling actuator, and the optical measurement instrument, an optical fiber array is disposed on the optical coupling actuator and located on an optical path generated by the optical measurement instrument, and the optical coupling verification method comprises:
loading a verification kit into the wafer prober;
driving, by the integrated control module, an upward-facing camera of the wafer prober to be aligned with the optical fiber array;
driving, by the integrated control module, a downward-facing camera of the wafer prober to be aligned with the verification kit;
obtaining, by the integrated control module, a relative position relation between the optical fiber array and the verification kit in the wafer prober; and
driving, by the integrated control module, the wafer prober, the optical measurement instrument, and the optical coupling actuator to perform optical coupling verification on the optical fiber array and the verification kit to obtain characteristics variation of light of the optical path.

2. The optical coupling verification method according to claim 1, wherein the verification kit comprises a standard chip comprising an optical waveguide having at least one length and a coupler corresponding to the number of the optical fiber array.

3. The optical coupling verification method according to claim 2, wherein the verification kit is a tray carrying at least one of the standard chip, the tray has at least one mark, and the optical coupling verification method further comprises:
loading the tray onto a stage of the wafer prober; and
aligning the downward-facing camera with the at least one mark and the standard chip.

4. The optical coupling verification method according to claim 2, wherein the verification kit is a silicon photonics wafer having a plurality of the standard chips, and the optical coupling verification method further comprises:
loading the silicon photonics wafer onto a stage of the wafer prober; and
aligning the downward-facing camera with the silicon photonics wafer and at least one of the standard chips.

5. The optical coupling verification method according to claim 1, wherein the verification kit is an optical power meter for detecting the characteristics of light.

6. The optical coupling verification method according to claim 5, further comprising:
aligning the downward-facing camera with an optical interface of the optical power meter.

7. The optical coupling verification method according to claim 5, wherein the wafer prober comprises a stage, and the upward-facing camera and the optical power meter are disposed on a side surface of the stage.

8. The optical coupling verification method according to claim 7, wherein the optical power meter is achievable to be raised and lowered on the side surface.

9. The optical coupling verification method according to claim 7, wherein the stage is a movable stage, and the upward-facing camera and the optical power meter move along with the movable stage in the wafer prober.

10. The optical coupling verification method according to claim 5, wherein the wafer prober comprises a probe testing platform and a moving shaft movably disposed in the probe testing platform, and the optical power meter is disposed on the moving shaft.

11. The optical coupling verification method according to claim 10, wherein the wafer prober further comprises a stage movably disposed in the probe testing platform of the wafer prober, and the upward-facing camera is disposed on a side surface of the stage.

12. The optical coupling verification method according to claim 1, wherein the wafer prober further comprises a stage movably disposed in a probe testing platform of the wafer prober, the downward-facing camera is fixed in the probe testing platform, the verification kit is loaded on the stage, and the optical coupling verification method further comprises:
driving the stage and the verification kit thereon to below the downward-facing camera for alignment.

13. The optical coupling verification method according to claim 1, wherein the wafer prober further comprises a stage movably disposed in a probe testing platform of the wafer prober, and the upward-facing camera is assembled on a side surface of the stage to move with the stage in the probe testing platform.

14. The optical coupling verification method according to claim 1, wherein the downward-facing camera is movably disposed in the wafer prober.

15. The optical coupling verification method according to claim 1, wherein when the characteristics variation of light meets a preset condition, a silicon photonics wafer to be tested is loaded into the wafer prober to perform optical coupling on the optical fiber array and the silicon photonics wafer to be tested and perform opto-electronic testing on the silicon photonics wafer to be tested after the optical coupling is completed.

16. The optical coupling verification method according to claim 1, wherein the characteristics variation of light comprises loss of light energy.
